(19) United States
(12) Patent Application Publication
(10) Pub. No.: US 2012/0247511 A1
(43) Pub. Date: Oct. 4, 2012

(54) METHOD FOR CLEANING THIN FILM FORMING APPARATUS, THIN FILM FORMING METHOD, AND THIN FILM FORMING APPARATUS

(75) Inventors: Mitsuhiro OKADA, Nirasaki City (JP); Yukio TOJO, Oshu-shi (JP); Kenji TAGO, Fuchu City (JP); Kazuaki NISHIMURA, Nirasaki City (JP)

(73) Assignee: TOKYO ELECTRON LIMITED, Tokyo (JP)

(21) Appl. No.: 13/431,467

(22) Filed: Mar. 27, 2012

(30) Foreign Application Priority Data
Mar. 29, 2011 (JP) 2011-073590

(51) Int. Cl. B08B 9/08; B08B 5/00; C23C 16/56

(52) U.S. Cl. 134/19; 427/248.1; 118/715

(57) ABSTRACT

A method for cleaning a thin film forming apparatus by removing extraneous matter attached to an interior of the thin film forming apparatus after supplying a treatment gas into a reaction chamber of the thin film forming apparatus and forming a thin film on an object to be processed, the method including: supplying a cleaning gas including fluorine gas, hydrogen fluoride gas, and chlorine gas into the reaction chamber heated to a predetermined temperature to remove the extraneous matter.

### CROSS-REFERENCE TO RELATED APPLICATION

This application claims the benefit of Japanese Patent Application No. 2011-073590, filed on Mar. 29, 2011, in the Japan Patent Office, the disclosure of which is incorporated herein in its entirety by reference.

### TECHNICAL FIELD

The present disclosure relates to a method for cleaning a thin film forming apparatus, a thin film forming method, and a thin film forming apparatus.

### BACKGROUND

In a process of fabricating a semiconductor device, thin film formation processing is performed to form a thin film such as a silicon oxide film, a silicon nitride film, and the like on an object to be processed, e.g., a semiconductor wafer, through a process such as chemical vapor deposition (CVD) or the like. In such thin film formation processing, a treatment gas is supplied into a reaction chamber set to have, for example, a predetermined temperature and pressure to cause a thermal reaction to the treatment gas, and a reaction product generated from the thermal reaction is deposited on a surface of the semiconductor wafer, thus forming a thin film on the surface of the semiconductor wafer.

However, the reaction product generated from the thin film formation processing may be deposited (attached) on the interior of a heat treatment device, as well as on the surface of the semiconductor wafer. When the thin film formation processing continues in a state in which the reaction product is attached to the interior of the heat processing device, the reaction product may resultantly peel off, thus readily generating particles. Further, when the particles attach to the semiconductor wafer, production yield of a semiconductor fabrication device is degraded.

Thus, after the thin film formation processing is performed several times, a reaction tube is heated by a heater to have a predetermined temperature, and a cleaning gas, e.g., fluorine gas and hydrogen fluoride gas, is supplied into the heated reaction tube to remove (etch) the reaction product attached to the interior of the heat treatment device, thereby cleaning the heat treatment device.

However, in the cleaning of the thin film forming apparatus, as mentioned above, the etching rate of the reaction product (extraneous matter) attached to the interior of the device needs to be increased.

### SUMMARY

The present disclosure provides a method for cleaning a thin film forming apparatus capable of increasing an etching rate of extraneous matter attached to the interior of a device.

According to one embodiment of the present disclosure, provided is a method for cleaning a thin film forming apparatus by removing extraneous matter attached to an interior of the thin film forming apparatus after supplying a treatment gas into a reaction chamber of the thin film forming apparatus and forming a thin film on an object to be processed, the method including supplying a cleaning gas including fluorine gas, hydrogen fluoride gas, and chlorine gas into the reaction chamber heated to a predetermined temperature to remove the extraneous matter to thereby clean the interior of the thin film forming apparatus.

According to another embodiment of the present disclosure, provided is a thin film forming apparatus for forming a thin film on an object to be processed by supplying a treatment gas into a reaction chamber accommodating the object to be processed, the apparatus including a heating unit configured to heat an interior of the reaction chamber to a predetermined temperature; a cleaning gas supply unit configured to supply a cleaning gas including fluorine gas, hydrogen fluoride gas, and chlorine gas to the interior of the reaction chamber; and a controller configured to control the thin film forming apparatus, wherein, in a state in which the interior of the reaction chamber is heated to have a predetermined temperature by controlling the heating unit, the controller controls the cleaning gas supply unit to supply a cleaning gas to the interior of the reaction chamber to activate the cleaning gas and remove extraneous matter by the activated cleaning gas to thereby clean the interior of the thin film forming apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a heat treatment device according to an embodiment of the present disclosure.

FIG. 2 is a block diagram showing a configuration of the controller in FIG. 1.

FIG. 3 is a diagram for explaining a method for forming a silicon nitride film.

FIG. 4 is a table showing an etching rate of the silicon nitride film.

### DETAILED DESCRIPTION

Exemplary embodiments of the present disclosure will now be described in detail with reference to the drawings.

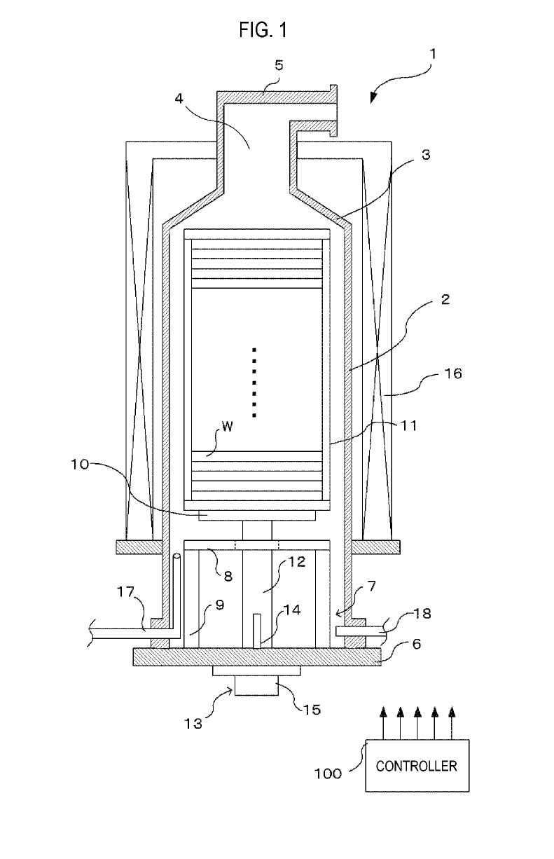

Hereinafter, a method for cleaning a film forming apparatus, a thin film forming method, and a thin film forming apparatus according to the present disclosure will be described. In the present embodiment, a case in which a batch type vertical heat treatment device, illustrated in FIG. 1, is used as the thin film forming apparatus according to the present disclosure and a silicon nitride film is formed on a semiconductor wafer will be described as an example.

As illustrated in FIG. 1, a heat treatment device 1 includes a reaction tube 2 forming a reaction chamber. The reaction tube 2 has, for example, a substantially cylindrical shape whose longitudinal direction is along a vertical direction. The reaction tube 2 is made of a material, e.g., quartz, having excellent heat resistance and corrosion resistance.

A top portion 3 having a substantially conical shape is installed at an upper end portion of the reaction tube 2 such that a diameter thereof is reduced toward an upper end portion of the top portion 3. An exhaust hole 4 is installed at the center of the upper end portion of the top portion 3 in order to exhaust gas within the reaction tube 2, and an exhaust pipe 5 is airtightly connected to the exhaust hole 4. A pressure adjustment mechanism such as a valve (not shown), a vacuum pump 127 to be described later, and the like are installed at the exhaust pipe 5 to control the interior of the reaction tube 2 to have a desired pressure (vacuum degree).

A cover 6 is disposed at a lower end portion of the reaction tube 2. The cover 6 is made of a material, e.g., quartz, having excellent heat resistance and corrosion resistance. In addition, the cover 6 is configured to move up and down by a boat elevator 128 to be described later. When the cover 6 is lifted by the boat elevator 128, the lower portion (throat portion) of the reaction tube 2 is closed, and when the cover 6 is lowered by the boat elevator 128, the lower portion (throat portion) of the reaction tube 2 is opened.

A warm keeping container 7 is installed at an upper portion of the cover 6. The warm keeping container 7 is mainly comprised of a planar heater 8 configured as a resistance heating element for preventing a temperature drop within the reaction tube 2 due to heat dissipation from the throat portion of the reaction tube 2, and a cylindrical support 9 for supporting the heater 8 at a predetermined height from an upper surface of the cover 6.

Further, a rotary table 10 is installed at an upper portion of the warm keeping container 7. The rotary table 10 serves as a loading table for rotatably loading a wafer boat 11 for accommodating an object to be processed, e.g., a semiconductor wafer W. Specifically, a rotary prop 12 is installed at a lower side of the rotary table 10, and the rotary prop 12 is configured to penetrate a central portion of the heater and is connected to a rotary mechanism 13 for rotating the rotary table 10. The rotary mechanism 13 is mainly comprised of a motor (not shown) and a rotary introduction part 15 having a rotary shaft 14 configured to airtightly penetrate from a lower surface to an upper surface of the cover 6. The rotary shaft 14 is connected to the rotary prop 12 and transfers the rotary power of the motor to the rotary table 10 through the rotary prop 12. Accordingly, when the rotary shaft 14 is rotated by the motor of the rotary mechanism 13, the rotary power of the rotary shaft 14 is transferred to the rotary prop 12 to rotate the rotary table 10.

A wafer boat 11 is loaded on the rotary table 10. The wafer boat 11 is configured to accommodate a plurality of sheets of the semiconductor wafers W at predetermined intervals in a vertical direction. When the rotary table 10 is rotated, the wafer boat 11 is also rotated, and accordingly, the semiconductor wafers W accommodated within the wafer boat 11 are rotated. The wafer boat 11 is made of a material, e.g., quartz, having excellent heat resistance and corrosion resistance.

Further, a heater 16 for temperature elevation configured as, for example, a resistance heating element is installed around the reaction tube 2 to surround it. The interior of the reaction tube 2 is heated to a predetermined temperature by the heater 16, and as a result, the semiconductor wafers W are heated to a predetermined temperature.

A plurality of treatment gas introduction pipes 17 penetrates (are connected to) a side wall in the vicinity of a lower end portion of the reaction tube 2. Only a single treatment gas introduction pipe 17 is shown in FIG. 1. A treatment gas supply source (not shown) is connected to the treatment gas introduction pipe 17, and a desired amount of treatment gas is supplied to the reaction tube 2 through the treatment gas introduction pipe 17 from the treatment gas supply source. The treatment gas includes a film forming gas, a cleaning gas, and the like.

The film forming gas is a gas for forming a thin film on the semiconductor wafer W, and a desired gas is used according to the type of a thin film to be formed. In the present embodiment, a silicon nitride film is formed on the semiconductor wafer W. Thus, a gas including hexachloro disilane (Si₂Cl₆) and ammonia (NH₃) is used as the treatment gas.

The cleaning gas is a gas used to remove extraneous matter attached to the interior of the heat treatment device 1, and a gas including fluorine (F₂) gas, hydrogen fluoride (HF) gas, and chlorine (Cl₂) gas is used as the cleaning gas. In the present embodiment, as explained hereinafter, a gas including fluorine gas, hydrogen fluoride gas, chlorine gas, and nitrogen gas is used as the cleaning gas.

A purge gas supply pipe 18 penetrates a lateral surface in the vicinity of the lower end portion of the reaction tube 2. A purge gas supply source (not shown) is connected to the purge gas supply pipe 18, and a desired amount of purge gas, e.g., nitrogen (N₂), is supplied to the reaction tube 2 through the purge gas supply pipe 18 from the purge gas supply source.

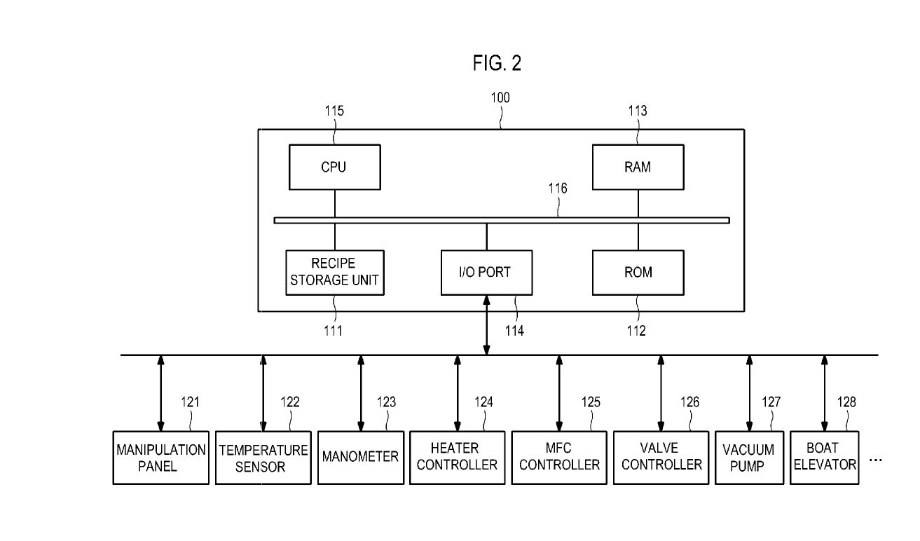

The heat treatment device 1 also includes a controller 100 for controlling each part of the device. FIG. 2 illustrates the configuration of the controller 100. As shown in FIG. 2, a manipulation panel 121, a temperature sensor (group) 122, a manometer (group) 123, a heater controller 124, a MFC controller 125, a valve controller 126, a vacuum pump 127, a boat elevator 128, and the like are connected to the controller 100.

The manipulation panel 121 includes a display screen and a manipulation button, transfers a manipulation instruction from an operator to the controller 100, and displays various types of information from the controller 100 on the display screen.

The temperature sensor (group) 122 measures a temperature of a thermocouple (T/C) installed in each zone within the reaction tube 2, a temperature of a T/C installed in each zone within the heater 16, a temperature within the exhaust pipe 5, and the like, and notifies the controller 100 of the temperature measurement values.

The manometer (group) 123 measures a pressure of each part within the reaction tube 2, the exhaust pipe 5, and the like, and notifies the controller 100 of the pressure measurement values.

The heater controller 124 individually controls the heater 8 and the heater 16. The heater controller 124 is electrically connected to the heater 8 and the heater 16 to heat them in response to an instruction from the controller 100, measures power consumption of the heater 8 and the heater 16 individually, and notifies the controller 100.

The MFC controller 125 controls a mass flow controller (not shown) installed at the treatment gas introduction pipe 17 and the purge gas supply pipe 18 to control a flow rate of a gases flowing therein into an amount indicated by the controller 100, measures an actual flow rate of the gases, and notifies the controller 100.

The valve controller 126 controls an opening degree of the valves disposed in the respective pipes to a value indicated by the controller 100. The vacuum pump 127 is connected to the exhaust pipe 5 and exhausts the gas within the reaction tube 2.

The boat elevator 128 lifts the cover 6 to load the wafer boat 11 (semiconductor wafers W) loaded on the rotary table 10 into the reaction tube 2, and lowers the cover 6 to unload the wafer boat 11 (semiconductor wafers W) loaded on the rotary table 10 from the interior of the reaction tube 2.

The controller 100 includes a recipe storage unit 111, a ROM 112, a RAM 113, an I/O port 114, and a CPU 115, and a bus 116 for connecting these elements.

The recipe storage unit 111 stores a recipe for set-up and a plurality of recipes for processing. At an initial stage of fabricating the heat treatment device 1, only the recipe for set-up is stored in the recipe storage unit 111. The recipe for set-up is executed in generating a heat model, or the like according to each heat treatment device. The recipe for processing is prepared for each heat treatment (process) actually performed by the user and defines a change in temperature of each part, a change in pressure in the reaction tube 2, a timing for starting and stopping supply of a treatment gas, an amount of supply of the treatment gas, and the like from, for example, the time of loading the semiconductor wafers W into the reaction tube 2 to the time of unloading the processed wafers W.

The ROM 112, which may be comprised of an EEPROM, a flash memory, a hard disk, and the like, is a recording medium for storing an operation program, or the like of the CPU 115.

The RAM 113 serves as a work area, or the like of the CPU 115.

The I/O port 114, which is connected to the manipulation panel 121, the temperature sensor 122, the manometer 123, the heater controller 124, the MFC controller 125, the valve controller 126, the vacuum pump 127, the boat elevator 128 and the like, controls the input-output of data or a signal.

The CPU (Central Processing Unit) 115 forms the nucleus of the controller 100, executes a control program stored in the ROM 112, and controls the operation of the heat treatment device 1 based on the recipe (recipe for processing) stored in the recipe storage unit 111 according to an instruction from the manipulation panel 121. That is, the CPU 115 controls the temperature sensor (group) 122, the manometer (group) 123, the MFC controller 125 and the like to measure the temperature, pressure, flow rate and the like of each part within the reaction tube 2, the treatment gas introduction pipe 17, and the exhaust pipe 5; outputs a control signal and the like to the heater controller 124, the MFC controller 125, the valve controller 126, the vacuum pump 127 and the like based on the measured data; and controls each part to follow the recipe for processing.

The bus 116 delivers information between the respective parts.

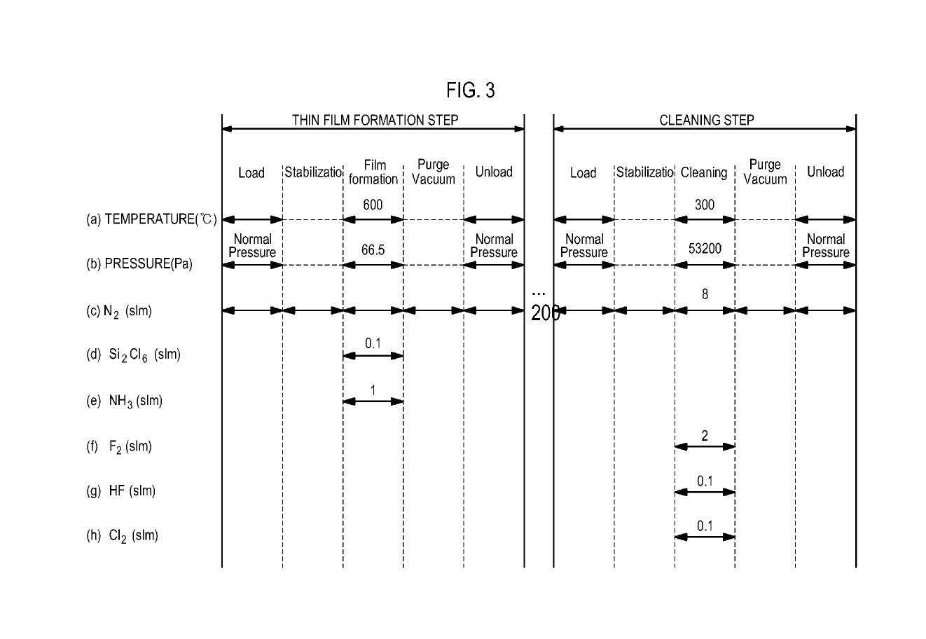

Next, a thin film forming method including a method for cleaning the heat treatment device 1 configured as described above will be described. The thin film forming method according to the present disclosure includes a thin film formation step of forming a thin film on an object to be processed, and a cleaning step of cleaning extraneous matter attached to the interior of the thin film forming apparatus, which is also a method for cleaning the thin film forming apparatus according to the present disclosure. In the present embodiment, the method for cleaning a thin film forming apparatus and the thin film forming method according to the present disclosure will be described with reference to the recipes illustrated in FIG. 3 by taking a case in which a thin film formation step of forming a silicon nitride film on the semiconductor wafer W and a cleaning step of removing (cleaning) silicon nitride attached to the interior of the heat treatment device 1 by the thin film formation step are performed as an example. Further, in the following description, the operations of the respective parts that constitute the heat treatment device 1 are controlled by the controller 100 (CPU 115).

First, the thin film formation step will be described.

A loading step of accommodating (loading) a semiconductor wafer W as the object to be processed into the reaction tube 2 is executed. Specifically, in a state in which the cover 6 is lowered by the boat elevator 128, as shown at (c) in FIG. 3, a predetermined amount of nitrogen is supplied into the reaction tube 2 from the purge gas supply pipe 18 and, simultaneously, the interior of the reaction tube 2 is set to have a predetermined loading temperature by the heater 16.

Next, the wafer boat 11 in which the semiconductor wafer W, on which a silicon nitride film is to be formed, is accommodated is loaded on the cover 6 (rotary table 10). Then, the cover 6 is lifted by the boat elevator 128 to load the semiconductor wafer W (wafer boat 11) into the reaction tube 2 (loading process).

Thereafter, a predetermined amount of nitrogen, as shown at (c) in FIG. 3, is supplied to the interior of the reaction tube 2 from the purge gas supply pipe 18, and the interior of the reaction tube 2 is set to have a predetermined pressure, e.g., 66.5 Pa (0.5 Torr) as shown at (b) in FIG. 3. Further, the interior of the reaction tube 2 is set to have a predetermined temperature, e.g., 600 degrees C., as shown at (a) in FIG. 3, by the heater 16. The decompression and heating settings are maintained until the reaction tube 2 is stabilized at the predetermined pressure and the predetermined temperature (stabilization process).

When the interior of the reaction tube 2 is stabilized at the predetermined pressure and predetermined temperature, supply of the nitrogen gas from the purge gas supply pipe 18 is stopped. Then, a predetermined amount, e.g., 0.1 slm, of hexachlorodisilane (Si₂Cl₆), as shown at (d) in FIG. 3, and a predetermined amount, e.g., 1 slm, of ammonia (NH₃), as shown at (e) in FIG. 3, are introduced as the treatment gas into the reaction tube 2 from the treatment gas introduction pipe 17.

The hexachlorodisilane and ammonia introduced into the reaction tube 2 are thermally decomposed by the heat within the reaction tube 2, and silicon nitride (Si₃N₄) is deposited on the surface of the semiconductor wafer W. Accordingly, a silicon nitride film (Si₃N₄ film) is formed on the surface of the semiconductor wafer W (film formation process).

When the silicon nitride film having a predetermined thickness is formed on the surface of the semiconductor wafer W, the supply of hexachlorodisilane and ammonia from the treatment gas introduction pipe 17 is stopped. In addition, the supply of nitrogen from the purge gas supply pipe 18 is stopped. Then, the gas within the reaction tube 2 is discharged and, simultaneously, a predetermined amount of nitrogen, for example, as shown at (c) in FIG. 3, is supplied to the interior of the reaction tube 2 from the purge gas supply pipe 18 such that the gas within the reaction tube 2 is discharged to the outside of the reaction tube 2 (purge vacuum process). Further, in order to reliably discharge the gas within the reaction tube 2, discharging the gas within the reaction tube 2 and supplying the nitrogen gas are preferably repeated several times in some embodiments.

Finally, a predetermined amount of nitrogen gas is supplied from the purge gas supply pipe 18 to return the interior of the reaction tube 2 to a normal pressure, and the cover 6 is lowered by the boat elevator 128 to unload the wafer boat 11 (semiconductor wafer W) from the reaction tube 2 (unloading process).

When the thin film formation steps as mentioned above are performed several times, the silicon nitride generated by the thin film formation step is deposited (attached) not only on the semiconductor wafer W but also on the interior of the reaction tube 2, various jigs or the like. Thus, after the thin film formation step is performed a predetermined number of times, a cleaning step of removing the silicon nitride attached to the interior of the heat treatment device 1 is performed. The cleaning step is performed by supplying a cleaning gas including fluorine (F₂) gas, hydrogen fluoride (HF) gas, and chlorine (Cl₂) gas, and nitrogen (N₂) gas as a dilution gas to the interior of the heat treatment device 1 (reaction tube 2). Hereinafter, the cleaning process of the heat treatment device 1 will be described.

First, in a state in which the cover 6 is lowered by the boat elevator 128, a predetermined amount of nitrogen, as shown at (c) in FIG. 3, is supplied to the interior of the reaction tube 2 from the purge gas supply pipe 18 and, simultaneously, the interior of the reaction tube 2 is set to have a predetermined loading temperature by the heater for temperature elevation 16.

Next, the wafer boat 11 in which a semiconductor wafer W is not accommodated is loaded on the cover 6 (the rotary table 10). Then, the cover 6 is lifted by the boat elevator 128 to load the wafer boat 11 to the interior of the reaction tube 2 (loading process).

Thereafter, a predetermined amount of nitrogen, as shown at (c) in FIG. 3, is supplied to the interior of the reaction tube 2 from the purge gas supply pipe 18, and the interior of the reaction tube 2 is set to have a predetermined pressure, e.g., 53200 Pa (400 Torr), as shown at (b) in FIG. 3. Further, the interior of the reaction tube 2 is set to have a predetermined temperature, e.g., 300 degrees C., as shown at (a) in FIG. 3, by the heater 16. The decompression and heating manipulations are performed until the reaction tube 2 is stabilized at the predetermined pressure and the predetermined temperature (stabilization process).

Here, the pressure within the reaction tube 2 is set to range from 1330 Pa to 80000 Pa (range from 10 Torr to 600 Torr). If the pressure within the reaction tube 2 is lower than 1330 Pa, an etching rate of the silicon nitride (extraneous matter) is likely to be lowered, and if the pressure within the reaction tube 2 is higher than 80000 Pa, an etching rate of quartz is likely to be increased and a selectivity ratio is lowered. In some embodiments, the pressure within the reaction tube 2 ranges from 13300 Pa to 53200 Pa (ranges from 100 Torr to 400 Torr).

Further, the temperature within the reaction tube 2 is in some embodiments set to range from 200 to 600 degrees C. If the temperature within the reaction tube 2 is lower than 200 degrees C., the etching rate of the silicon nitride (extraneous matter) is likely to be lowered, and if the temperature within the reaction tube 2 is higher than 600 degrees C., the etching rate of quartz is likely to be increased and the selectivity ratio is lowered. In other embodiments, the temperature within the reaction tube 2 is set to range from 250 to 400 degrees C.

When the interior of the reaction tube 2 is stabilized at the predetermined pressure and the predetermined temperature, supply of the nitrogen gas from the purge gas supply pipe 18 is stopped. Then, a predetermined amount, e.g., 2 slm, of fluorine gas, as shown at (f) in FIG. 3, a predetermined amount, e.g., 0.1 slm, of hydrogen fluoride gas, as shown at (g) in FIG. 3, a predetermined amount, e.g., 0.1 slm, of chlorine gas, as shown at (h) in FIG. 3, and a predetermined amount, e.g., 8 slm, of nitrogen gas, as shown at (c) in FIG. 3, are introduced as the cleaning gas into the reaction tube 2 from the treatment gas introduction pipe 17.

The cleaning gas introduced into the reaction tube 2 is thermally decomposed by the heat within the reaction tube 2 and the fluorine gas included in the cleaning gas is activated, i.e., changed into a state of having free atoms with reactivity. In addition, since the cleaning gas includes the hydrogen fluoride gas and the chlorine gas, the activation of the fluorine gas is accelerated. The cleaning gas including the activated fluorine gas is supplied to the interior of the reaction tube 2 and contacts the silicon nitride attached to the interior of the heat treatment device 1 such as the inner walls of the reaction tube 2, the exhaust hole 4, the exhaust pipe 5, and the like and various jigs of the wafer boat 11, the warm keeping container 7, and the like such that the silicon nitride is etched. Accordingly, the silicon nitride attached to the interior of the heat treatment device 1 is removed (cleaning process).

When the silicon nitride attached to the interior of the heat treatment device 1 is removed, supply of the cleaning gas from the treatment gas introduction pipe 17 is stopped. Then, the gas within the reaction tube 2 is discharged and, simultaneously, a predetermined amount of nitrogen, for example, as shown at (c) in FIG. 3, is supplied to the interior of the reaction tube 2 from the purge gas supply pipe 18 such that the gas within the reaction tube 2 is discharged to the outside of the reaction tube 2 (purge vacuum process).

Finally, a predetermined amount of nitrogen gas is supplied from the purge gas supply pipe 18 to return the interior of the reaction tube 2 to a normal pressure, and the cover 6 is lowered by the boat elevator 128 to unload the wafer boat 11 from the reaction tube 2 (unloading process). Then, the wafer boat 11 in which the semiconductor wafer W is now accommodated is loaded onto the cover 6, and the thin film formation step is executed again, whereby a silicon nitride film can be formed on the semiconductor wafer W in a state in which silicon nitride is not attached to the interior of the heat treatment device 1.

In order to confirm the effects according to the present embodiment, an etching rate of the cleaning gas was obtained. In the present example, three types of test pieces, i.e., a test piece made of quartz, a test piece made of SiC, and a test piece obtained by forming silicon nitride film having a thickness of 3 μm on a quartz piece, were accommodated in the wafer boat 11, the wafer boat 11 was accommodated in the reaction tube 2, the cleaning gas was supplied to the interior of the reaction tube 2 to perform the cleaning processing of the respective test pieces, and then, an etching rate of each test piece was obtained.

In a first example, as in the cleaning step according to the foregoing embodiment, the cleaning gas including 2 slm of fluorine gas, 0.1 slm of hydrogen fluoride gas, 0.1 slm of chlorine gas, and 8 slm of nitrogen gas was used. In a first comparative example, a cleansing gas including 2 slm of fluorine gas and 8 slm of nitrogen gas was used, and in a second comparative example, a cleaning gas including 2 slm of fluorine gas, 0.1 slm of hydrogen fluoride gas and 8 slm of nitrogen gas was used.

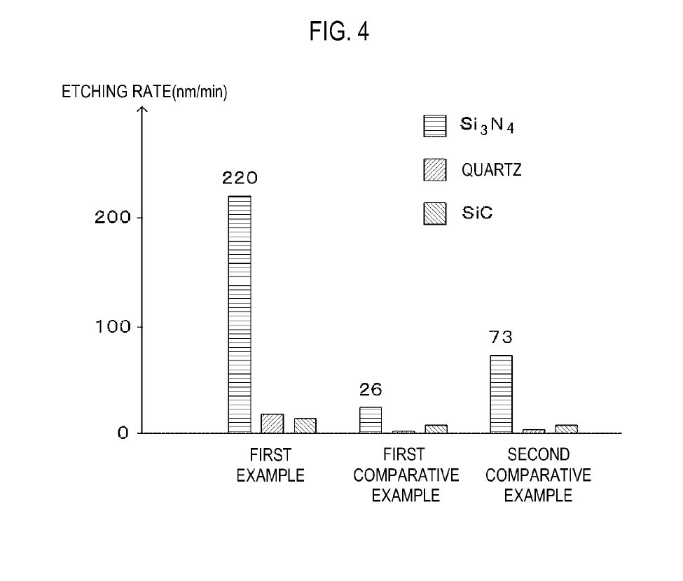

For the etching rates, the weight of each of the test pieces was measured before and after the cleaning, and the etching rates were calculated based on the change in the weight due to the cleaning operation. For the measurement, as in the cleaning step according to the foregoing embodiment, the temperature within the reaction tube 2 was set to 300 degrees C. and the pressure within the reaction tube 2 was set to 53200 Pa (400 Torr). FIG. 4 illustrates the results obtained.

As illustrated in FIG. 4, it can be seen from the first example and the first comparative example that the etching rate of the silicon nitride was increased by 9 times by adding the hydrogen fluoride gas and chlorine gas to the fluorine gas without increasing the temperature of the reaction tube 2. In addition, it can be seen from the first example and the second comparative example that the etching rate of the silicon nitride was increased by 3 times by adding the chlorine gas to the fluorine gas and hydrogen fluoride gas without increasing the temperature of the reaction tube 2. In this manner, it was confirmed that in the cleaning of the thin film forming apparatus to remove extraneous matter within the heat treatment device 1, the etching rate of the silicon nitride can be significantly increased by using a cleaning gas including a fluorine gas, a hydrogen fluoride gas, and a chlorine gas.

As described above, according to the present embodiment, the etching rate of the silicon nitride can be significantly increased by using the cleaning gas including the fluorine gas, the hydrogen fluoride gas, and the chlorine gas.

Further, the present disclosure can be variably modified and applied without being limited to the foregoing embodiments. Hereinafter, different embodiments applicable to the present disclosure will be described.

In the present embodiment, the case in which silicon nitride attached to the interior of the heat treatment device 1 is removed is taken as an example, but the extraneous matter attached to the interior of the heat treatment device 1 is not limited to silicon nitride. For example, the extraneous matter may be silicon oxide, polysilicon, titanium oxide, tantalum oxide, silica, silicon germanium (SiGe), BSTO (BaSrTiO₃), STO (SrTiO₃), or the like. Further, the extraneous matter may be a reaction by-product, e.g., ammonium chloride, rather than being limited to the reaction product.

In the present embodiment, the case in which nitrogen gas is included as a dilution gas in the cleaning gas is taken as an example, but the dilution gas may not be included in the cleaning gas. However, since the setting of a cleaning time is facilitated by including the dilution gas, the dilution gas is included in the cleaning gas in some embodiments. The dilution gas may be in some instances an inert gas, and besides nitrogen gas, for example, a helium gas (He), a neon gas (Ne), and an argon gas (Ar) may be applied as the dilution gas.

In the present embodiment, in the cleaning process, the case in which the temperature within the reaction tube 2 is set to be 300 degrees C. and the pressure is set to be 53200 Pa (400 Torr) is taken as an example, but the temperature and pressure within the reaction tube 2 are not limited thereto. Further, for the frequency of the cleaning (cleaning step), the cleaning may be performed at every several thin film formation steps, or the cleaning may be performed, for example, at every thin film formation step. When the cleaning is performed at every thin film formation step, a life span of the materials within the device made of quartz, SiC, and the like can be further lengthened.

In the foregoing embodiment, the case of the batch type heat treatment device having a single tube structure is taken as an example as a thin film forming apparatus, but the present disclosure may be applied to, for example, a batch type vertical heat treatment device having a dual-tube structure including the reaction tube 2 comprised of an inner tube and an outer tube. Further, the present disclosure may also be applicable to a single piece type heat treatment device. Moreover, the object to be processed may also be applicable to, for example, a glass substrate used for an LCD, or the like, rather than being limited to the semiconductor wafer W.

The controller 100 according to an embodiment of the present disclosure can be realized by using a general computer system, rather than by using a dedicated system. For example, the controller 100 for executing the foregoing processing may be configured in a general purpose computer by installing a corresponding program from a recording medium (a flexible disk, a CD-ROM, or the like) which stores a program for executing the foregoing processing.

A means for providing the program is random. In addition to providing the program through a predetermined recording medium as described above, the program may be provided through, for example, a communication line, a communication network, a communication system, or the like. In this case, for example, the corresponding program may be posted on a bulletin board system (BBS) of a communication network and provided in an overlap manner in a carrier through a network. In addition, the foregoing processing may be executed by starting the program provided in this way and executing it like any other application programs under the control of an operating system (OS).

The present disclosure is useful for cleaning a thin film forming apparatus to remove and clean extraneous matter attached to the interior of the apparatus.

According to the present disclosure, it is possible to increase an etching rate of extraneous matter attached to the interior of a device.

While predetermined embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for cleaning a thin film forming apparatus by removing extraneous matter attached to an interior of the thin film forming apparatus after supplying a treatment gas into a reaction chamber of the thin film forming apparatus and forming a thin film on an object to be processed, the method comprising:
supplying a cleaning gas including fluorine gas, hydrogen fluoride gas, and chlorine gas into the reaction chamber heated to a predetermined temperature to remove the extraneous matter.

2. The method of claim 1, wherein, in supplying the cleaning gas, the cleaning gas is diluted by a dilution gas, and the diluted cleaning gas is supplied into the reaction chamber.

3. The method of claim 2, wherein an inert gas is used as the dilution gas.

4. The method of claim 1, wherein the thin film formed on the object to be processed is a silicon nitride film, and
in supplying the cleaning gas, the silicon nitride attached to the interior of the thin film forming apparatus when forming the silicon nitride film on the object to be processed is removed by the cleaning gas.

5. A thin film forming method, comprising:
forming a thin film on an object to be processed; and
cleaning an interior of a thin film forming apparatus by removing extraneous matter attached to the interior of the thin film forming apparatus by the method for cleaning a thin film forming apparatus described in claim 1.

6. A thin film forming apparatus for forming a thin film on an object to be processed by supplying a treatment gas into a reaction chamber accommodating the object to be processed, the apparatus comprising:
a heating unit configured to heat an interior of the reaction chamber to a predetermined temperature;
a cleaning gas supply unit configured to supply a cleaning gas including fluorine gas, hydrogen fluoride gas, and chlorine gas to the interior of the reaction chamber; and
a controller configured to control the thin film forming apparatus,
wherein, in a state in which the interior of the reaction chamber is heated to have a predetermined temperature by controlling the heating unit, the controller controls the cleaning gas supply unit to supply a cleaning gas to the interior of the reaction chamber to activate the cleaning gas and remove extraneous matter by the activated cleaning gas to thereby clean the interior of the thin film forming apparatus.
